(19) United States
(12) Patent Application Publication
(10) Pub. No.: US 2016/0060120 A1
(43) Pub. Date: Mar. 3, 2016

(54) METHOD OF PRODUCING REDUCED GRAPHENE OXIDE

(71) Applicants: Chuan Ling HU, New Taipei City (TW); H&H-T CO., LTD., Taipei City (TW)

(72) Inventor: Chuan Ling HU, New Taipei City (TW)

(73) Assignees: H&H-T CO., LTD., Taipei City (TW); Chuan Ling HU, New Taipei City (TW)

(21) Appl. No.: 14/841,050

(22) Filed: Aug. 31, 2015

(30) Foreign Application Priority Data
Sep. 1, 2014 (TW) 103130056

(51) Int. Cl. C01B 31/04; C23C 16/44; C23C 14/08; C23C 16/26; C23C 14/34; C23C 14/58

(52) U.S. Cl. CPC C01B 31/043; C23C 14/34; C23C 14/5846; C23C 14/08; C23C 16/26; C23C 16/44

(57) ABSTRACT

A method of producing reduced graphene oxide includes the steps of selecting a substrate; forming a carbon layer on a top of the substrate through sputter deposition or vapor deposition; subjecting the substrate and the carbon layer to an oxidation process at the same time for the carbon layer to form a graphene oxide layer; and subjecting the substrate and the graphene oxide layer to a reduction process at the same time to form a reduced graphene oxide layer on the substrate. With the method, low-cost, high-quality and large-area reduced graphene oxide sheet can be directly produced on different types of substrate, including metal and non-metal substrates.

### FIELD OF THE INVENTION

The present invention relates to a method of producing reduced graphene oxide, and more particularly, to a method of producing a large-area reduced graphene oxide sheet directly on a substrate through oxidation and reduction reaction.

### BACKGROUND OF THE INVENTION

Graphene is a plane film having hexagonal honeycomb lattice built with the sp² hybridized carbon atoms. Since it is a single-atom-thick two-dimensional material, graphene is currently the thinnest and the most rigid nanomaterial in the world. Due to its unique and excellent material characteristics, such as high mechanical strength, good heat conductivity and high carrier mobility, graphene material has been widely applied to the manufacture of clear touch screen, light-guide panel, solar battery and semiconductor products.

Conventionally, the methods for producing graphene include mechanical exfoliation, epitaxial growth, chemical vapor deposition (CVD), and reduction from graphene oxides.

With the mechanical exfoliation method, graphene sheets can be obtained by directly cleaving a relatively large crystal thereof. However, it is uneasy to control the size of the graphene sheets so obtained. As a result, the reliable production of large-area graphene sheets is not ensured.

With the epitaxial growth method, graphene is produced on a catalytic metal substrate or a silicon carbide substrate. However, a disadvantage of using the catalytic metal substrate is the difficulty in removing the metal material from the produced graphene and it is necessary to transfer the graphene onto an insulation substrate. On the other hand, with the silicon carbide substrate, the atom structure on the surface of the substrate will result in non-uniform layers of the produced graphene. For the time being, it is unable to produce large-area high-quality graphene using the epitaxial growth method.

In recent years, large-area graphene has been successfully produced on a transition metal through the chemical vapor deposition (CVD) method, which brings the related industrial fields to focus their research on the production of graphene through CVD. While the CVD method has the advantages of enabling the production of large-area graphene and the transfer of the produced graphene onto other substrates, a disadvantage thereof is the graphene formed on a copper or a nickel metal surface through CVD must be transferred onto a required substrate, and the produced graphene is usually subject to the problems of mechanical stress loss, residual contaminants and overly high production cost due to the additional transfer process.

Lastly, in the reduction from graphene oxides method, a first step is to oxidize graphite for producing graphene oxide. Then, in a second step, the graphene oxide is subjected to a reduction reaction under a high temperature, so that the graphene is restored to its initial lattice shape and has good electrical conductivity. However, according to the existing graphene production methods, such as the Brodie method (Brodie B. C., On the atomic weight of graphite [J]., Philosophical Transactions of the Royal Society, 1859, 149:249-59), the Hummers' method (W. S. Hummers & R. E. Offeman, Preparation of graphite oxide [J]., Journal of the American Chemical Society, 1958, 80:1339), and the Staudenmaier method (Y. Matsuo, K. Watanabe, T. Fukutsuka, et al., Characterization of n-hexadecyl-alkylamine-intercalated graphite oxide absorbents [J]., Carbon, 2003, 41 (8): 1545-1550), the produced graphene oxide is subjected to ultrasonic dissociation and is in the form of powder.

In view of the drawbacks in the conventional graphene production methods, it is desirable to develop a simple and economical method for quickly producing high-density, good-quality and large-area reduced graphene oxide sheets.

### SUMMARY OF THE INVENTION

A primary object of the present invention is to provide a method of producing reduced graphene oxide, so that low-cost, high-quality and large-area reduced graphene oxide sheets can be directly grown on different types of substrate, including metal and non-metal substrates. The method also has the advantage of involving simple processes to enable lowered production cost and largely upgraded industrial applicability of the reduced graphene oxide.

To achieve the above and other objects, the method of producing reduced graphene oxide according to a first embodiment of the present invention includes the following steps:
(A) selecting a substrate;
(B) forming a carbon layer on a top of the substrate through sputter deposition or vapor deposition;
(C) subjecting the substrate and the carbon layer to an oxidation process at the same time;
(D) the carbon layer forming a graphene oxide layer on the surface of the substrate after the oxidation process;
(E) subjecting the substrate and the graphene oxide layer to a reduction process at the same time; and
(F) the graphene oxide layer forming a reduced graphene oxide layer after the reduction process.

The substrate is selected from the group consisting of a metal substrate and a non-metal substrate.

A temperature for the oxidation process is set to range between 200 and 1500° C.

The oxidation process can be an atmosphere heat treatment, an atmosphere-oxygen reaction type heat treatment or a vacuum-oxygen reaction type heat treatment.

In the atmosphere-oxygen reaction type heat treatment, an amount of oxygen is supplied into an inert gas.

In the vacuum-oxygen reaction type heat treatment, an amount of oxygen is supplied into a vacuum space.

In an operable embodiment of the present invention, the metal substrate is a single metal material or alloy material.

In a preferred form of the first embodiment, the non-metal substrate can be any one of a ceramic substrate, a glass substrate, a semiconductor substrate, an engineering plastic substrate, a quartz substrate and a sapphire substrate, which all are formed of a non-metal material.

A second embodiment of the method according to the present invention is similar to the first embodiment, except that the metal substrate is formed of a metal material having another metal material sputter deposited or vapor deposited onto a top thereof, and the other metal material is selected from the group consisting of metal nickel and any alloy thereof.

In another operable form of the second embodiment, the non-metal substrate is formed of a non-metal material having a metal material sputter deposited or vapor deposited onto a top thereof, and the metal material is selected from the group consisting of metal nickel, a nickel alloy, chrome, a chrome alloy, titanium and a titanium alloy.

In a third embodiment of the method according to the present invention, the following steps are includes:
(A) selecting a substrate;
(B) forming a carbon layer on a top of the substrate through sputter deposition or vapor deposition;
(C) subjecting the substrate and the carbon layer to an oxidation process at the same time;
(D) the carbon layer forming a graphene oxide layer after the oxidation process;
(E) subjecting the substrate and the graphene oxide layer to a reduction process at the same time;
(F) the graphene oxide layer forming a reduced graphene oxide layer after the reduction process; and
(G) forming a patterned reduced graphene oxide layer by performing an anti-etching film attachment process, an exposure and development process, and an etching process on the reduced graphene oxide layer.

The substrate is selected from the group consisting of a metal substrate and a non-metal substrate.

A temperature for the oxidation process is set to range between 200 and 1500° C.

The oxidation process can be an atmosphere heat treatment, an atmosphere-oxygen reaction type heat treatment or a vacuum-oxygen reaction type heat treatment.

In the atmosphere-oxygen reaction type heat treatment, an amount of oxygen is supplied into an inert gas.

In the vacuum-oxygen reaction type heat treatment, an amount of oxygen is supplied into a vacuum space.

In an operable form of the third embodiment of the present invention, the metal substrate is a single metal material or alloy material.

In a preferred form of the third embodiment, the non-metal substrate can be any one of a ceramic substrate, a glass substrate, a semiconductor substrate, an engineering plastic substrate, a quartz substrate and a sapphire substrate, which all are formed of a non-metal material.

A fourth embodiment of the method according to the present invention is similar to the third embodiment, except that the metal substrate is formed of a metal material having another metal material sputter deposited or vapor deposited onto a top thereof, and the other metal material is selected from the group consisting of metal nickel and any alloy thereof.

In another operable form of the fourth embodiment, the non-metal substrate is formed of a non-metal material having a metal material sputter deposited or vapor deposited onto a top thereof, and the metal material is selected from the group consisting of metal nickel, a nickel alloy, chrome, a chrome alloy, titanium and a titanium alloy.

In a fifth embodiment of the method according to the present invention, the following steps are includes:
(A) selecting a substrate;
(B) forming a carbon layer on a top of the substrate through sputter deposition or vapor deposition;
(C) forming a patterned carbon layer by performing an anti-etching film attachment process, an exposure and development process, and an etching process on the carbon layer;
(D) removing the anti-etching film;
(E) subjecting the substrate and the patterned carbon layer to an oxidation process at the same time;
(F) the patterned carbon layer forming a patterned graphene oxide layer after the oxidation process;
(G) subjecting the substrate and the patterned graphene oxide layer to a reduction process at the same time; and
(H) the patterned graphene oxide layer forming a patterned reduced graphene oxide layer after the reduction process.

The substrate is selected from the group consisting of a metal substrate and a non-metal substrate.

A temperature for the oxidation process is set to range between 200 and 1500° C.

The oxidation process can be an atmosphere heat treatment, an atmosphere-oxygen reaction type heat treatment or a vacuum-oxygen reaction type heat treatment.

In the atmosphere-oxygen reaction type heat treatment, an amount of oxygen is supplied into an inert gas.

In the vacuum-oxygen reaction type heat treatment, an amount of oxygen is supplied into a vacuum space.

In an operable form of the fifth embodiment of the present invention, the metal substrate is a single metal material or alloy material.

In another operable form of the fifth embodiment, the non-metal substrate can be any one of a ceramic substrate, a glass substrate, a semiconductor substrate, an engineering plastic substrate, a quartz substrate and a sapphire substrate, which all are formed of a non-metal material. A sixth embodiment of the method according to the present invention is similar to the fifth embodiment, except that the metal substrate is formed of a metal material having another metal material sputter deposited or vapor deposited onto a top thereof, and the other metal material is selected from the group consisting of metal nickel and any alloy thereof.

In another operable form of the sixth embodiment, the non-metal substrate is formed of a non-metal material having a metal material sputter deposited or vapor deposited onto a top thereof, and the metal material is selected from the group consisting of metal nickel, a nickel alloy, chrome, a chrome alloy, titanium and a titanium alloy.

The method of the present invention is characterized in first forming a carbon layer on a top of a metal or a non-metal substrate through sputter deposition or vapor deposition, and then performing an oxidation process on the substrate and the carbon layer to produce a graphene oxide layer, and thereafter, performing a reduction process to form a layer of large-area reduced graphene oxide sheet on the substrate. With the above method, the production process is simple and economical while enables quick production of high-quality large-area reduced graphene oxide sheet on various types of substrate, giving the reduced graphene oxide sheet a wide range of industrial applicability.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flowchart showing the steps included in a first and a second embodiment of a method of producing reduced graphene oxide according to the present invention;

FIG. 2 is a pictorial description of the steps included in the first embodiment of the method according to the present invention;

FIGS. 3A and 3B respectively show a metal and a non-metal single-layer structured substrate usable with the first embodiment of the method according to the present invention;

FIG. 4 is a pictorial description of the steps included in the second embodiment of the method according to the present invention;

FIGS. 5A and 5B respectively show a metal and a non-metal composite-structured substrate usable with the second embodiment of the method according to the present invention;

FIG. 6 is a flowchart showing the steps included in a third and a fourth embodiment of the method according to the present invention;

FIGS. 7 and 8 are a pictorial description of the steps included in the third embodiment of the method according to the present invention;

FIGS. 9 and 10 are a pictorial description of the steps included in the fourth embodiment of the method according to the present invention;

FIG. 11 is a flowchart showing the steps included in a fifth and a sixth embodiment of the method according to the present invention;

FIGS. 12 and 13 are a pictorial description of the steps included in the fifth embodiment of the method according to the present invention;

FIGS. 14 and 15 are a pictorial description of the steps included in the sixth embodiment of the method according to the present invention;

FIG. 16 is a Raman spectrum of the reduced graphene oxide produced on an aluminum oxide substrate according to the method of the present invention; and

FIG. 17 is a Raman spectrum of the reduced graphene oxide produced on a copper substrate according to the method of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals. And, for the purpose of conciseness and clarity, the present invention is also briefly referred to as “the method” herein.

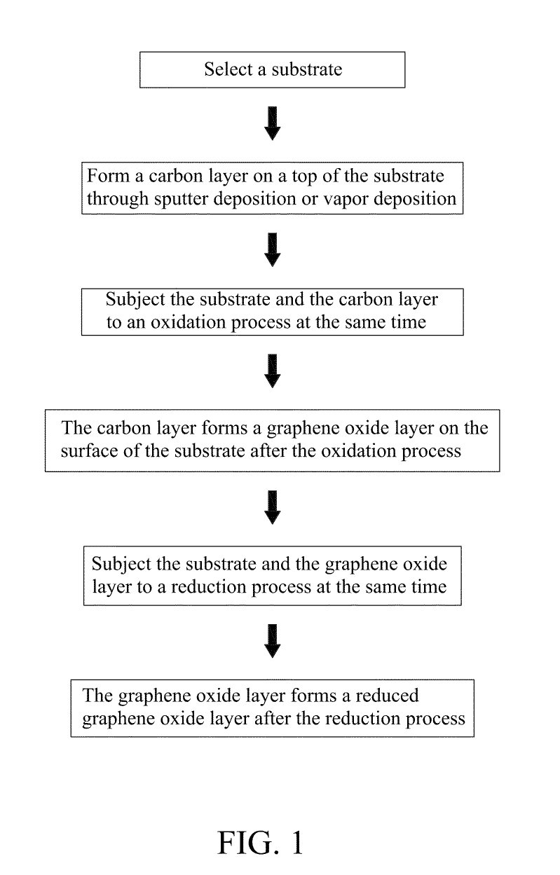

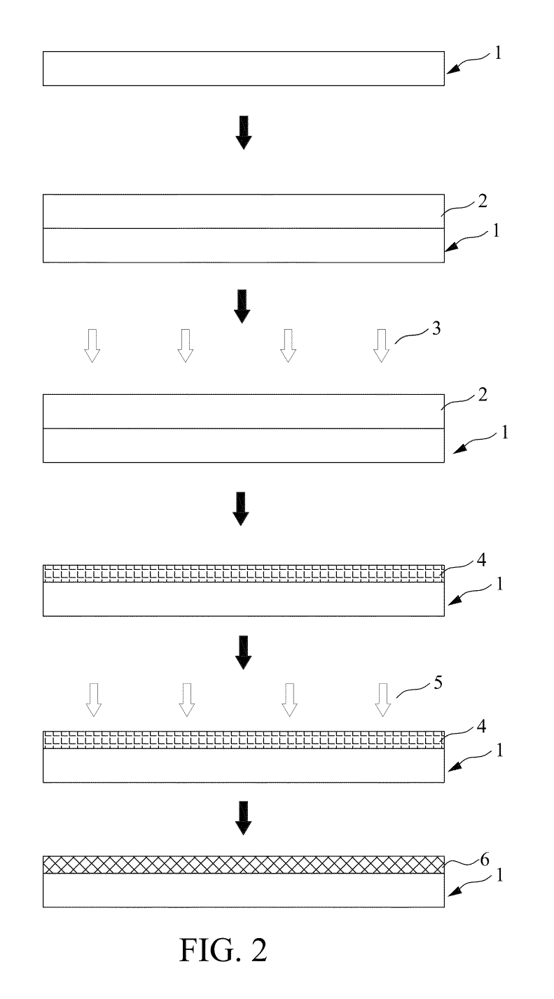

Please refer to FIGS. 1 and 2, which are flowchart and pictorial description, respectively, of the steps included in a first embodiment of a method of producing reduced graphene oxide according to the present invention. As shown, in the first embodiment thereof, the method of the present invention includes the following steps:
(A) selecting a substrate 1;
(B) forming a carbon layer 2 on a top of the substrate 1 through sputter deposition or vapor deposition;
(C) subjecting the substrate 1 and the carbon layer 2 to an oxidation process 3 at the same time;
(D) the carbon layer 2 forming a graphene oxide layer 4 on the surface of the substrate 1 after the oxidation process 3;
(E) subjecting the substrate 1 and the graphene oxide layer 4 to a reduction process 5 at the same time; and
(F) the graphene oxide layer 4 forming a reduced graphene oxide layer 6 after the reduction process 5.

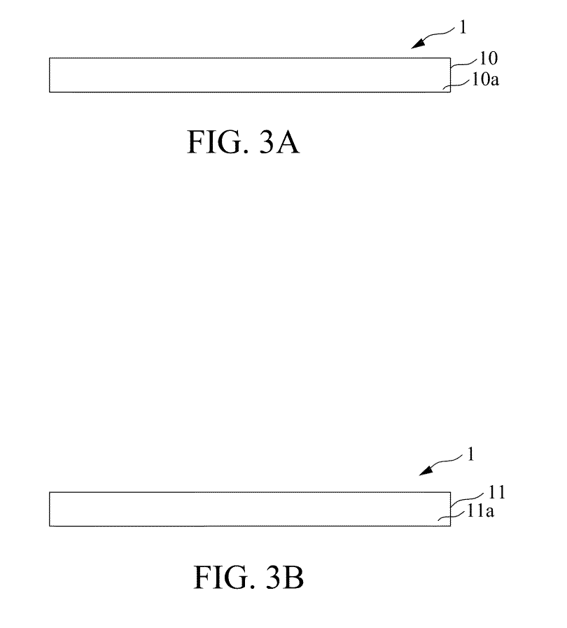

More specifically, in the step (A), a substrate 1 is selected. The substrate 1 can be a metal substrate 10 or a non-metal substrate 11. In the case of a metal substrate 10, the substrate 1 usable in the first embodiment can be formed of a single metal material 10a or a single alloy material, as shown in FIG. 3A. In an operable embodiment, the single metal material 10a or alloy material can be in the form of a metal sheet or metal foil produced through a rolling process using rolls. Alternatively, the metal sheet or the metal foil can be produced through electroplating or electroforming before a roll-to-roll processing. Therefore, the substrate 1 can be obtained through a quick and efficient manufacturing process.

According to another operable embodiment of the present invention, the metal substrate 10 can be a metal part obtained through a three-dimensional (3D) forming technique.

In the case of using a non-metal substrate 11, the non-metal substrate 11 is a single-layer structured substrate formed of a non-metal material 11a, as shown in FIG. 3B. In an operable embodiment of the present invention, the non-metal substrate 11 can be any one of a ceramic substrate, a glass substrate, a semiconductor substrate, an engineering plastic substrate, a quartz substrate and a sapphire substrate. The semiconductor substrate can be formed of gallium nitride (GaN), gallium arsenide (GaAs), gallium phosphide (GaP), zinc selenide (ZnSe), indium phosphide (InP), silicon carbide (SiC), silicon, or silicon dioxide (SiO₂).

More specifically, in the step (B), a carbon material is sputter deposited or vapor deposited onto a top of the substrate 1 to form a carbon layer 2 on the surface of the substrate 1.

More specifically, in the step (C), the substrate 1 and the carbon layer 2 formed thereon are together subjected to an oxidation process 3. The oxidation process 3 can be a vacuum-oxygen reaction type heat treatment or an atmosphere-oxygen reaction type heat treatment. The temperature for the heat treatment is set to range between 200 and 1500° C.

In the atmosphere-oxygen reaction type heat treatment, an inert gas and a very small amount of oxygen are used. More specifically, an object to be oxidized is positioned in a device, such as a furnace, and an inert gas and a small amount of oxygen is supplied into the furnace, so that the object undergoes a heat treatment in an inert atmosphere in the furnace.

In the vacuum-oxygen reaction type heat treatment, a very small amount of oxygen is supplied into a vacuum space. More specifically, an object to be oxidized is positioned in a vacuum device, and an amount of thin air is supplied into the vacuum device, so that the object undergoes a vacuum-oxygen reaction type heat treatment in the device.

According to another operable embodiment of the present invention, the oxidation process 3 can be an atmosphere heat treatment. In this case, the temperature for the oxidation process 3 is also set to range between 200 and 1500° C.

In the step (D), after the oxidation process 3, the carbon layer 2 is oxidized to carbon dioxide and forms a graphene oxide layer 4 on the surface of the substrate 1.

In the step (E), the substrate 1 and the graphene oxide layer 4 formed thereon are together subjected to a reduction process 5. The reduction process 5 can be a vacuum high-temperature process, in which the temperature is set to range between 200 and 1500° C.

The vacuum high-temperature process is a heat treatment performed in a vacuum environment (<10⁻³ torr).

According to another operable embodiment of the present invention, in the step (E), the substrate 1 and the graphene oxide layer 4 formed thereon are together subjected to a reduction process 5, which is a chemical reduction process. In the chemical reduction process, chemicals used can be any one of citric acid, sodium citrate, vitamin C, hydrazine, sodium borohydride, hydroquinone, sodium sulfite, hydroiodic acid, an alkaline solution, benzyl alcohol and butylmagnesium chloride, or a combination of any two of the aforesaid chemicals.

Alternatively, the reduction process 5 can be a laser reduction process, in which the high energy of laser is used to reduce the graphene oxide, so that the graphene oxide layer 4 is reduced to a reduced graphene oxide layer 6.

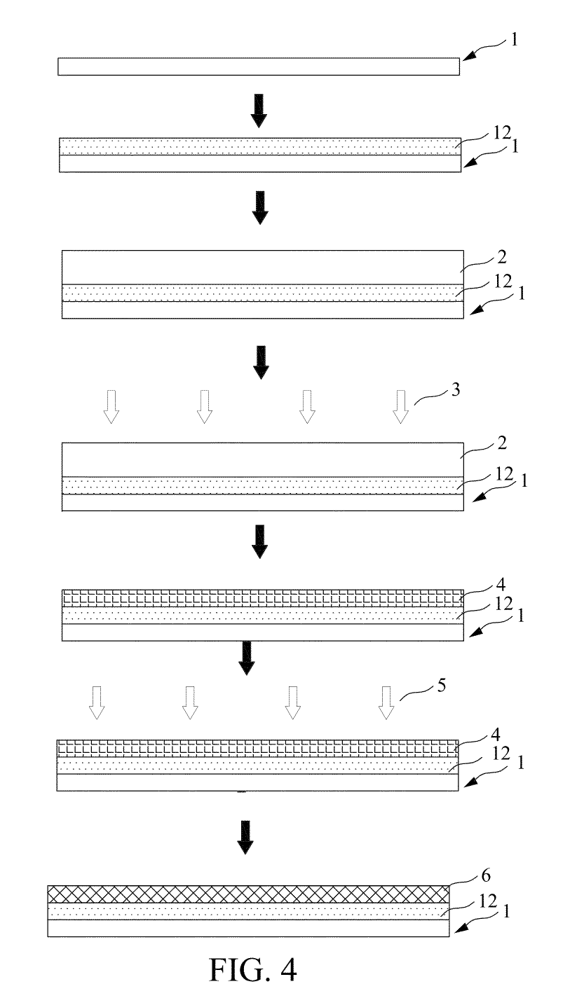

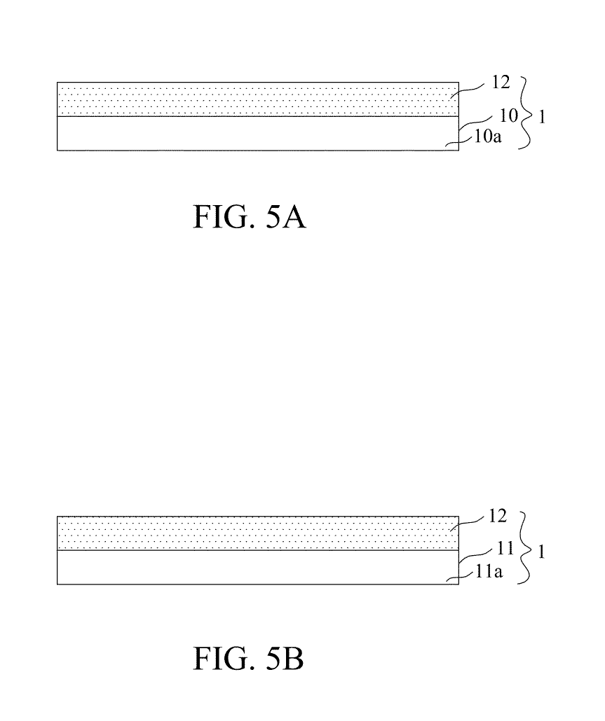

Please refer to FIG. 1 along with FIGS. 4 and 5, in which a second embodiment of the method according to the present invention is illustrated. The second embodiment is different from the first embodiment only in the step (A). Since all other steps from (B) to (F) are the same as those in the first embodiment, they are not repeatedly described herein.

In the second embodiment, the substrate 1 selected in the step (A) can be formed of a metal material 10a having another metal material 12, such as metal nickel or a nickel alloy, sputter deposited or vapor deposited onto a top thereof, and is therefore a dual-layer structured substrate 1, as shown in FIG. 5A.

Alternatively, according to another operable form of the second embodiment, the substrate 1 selected in the step (A) can be formed of a non-metal material 11 a having a metal material 12, such as metal nickel, a nickel alloy, chrome, a chrome alloy, titanium or a titanium alloy, sputter deposited or vapor deposited onto a top thereof, and is therefore a dual-layer structured substrate 1, as shown in FIG. 5B.

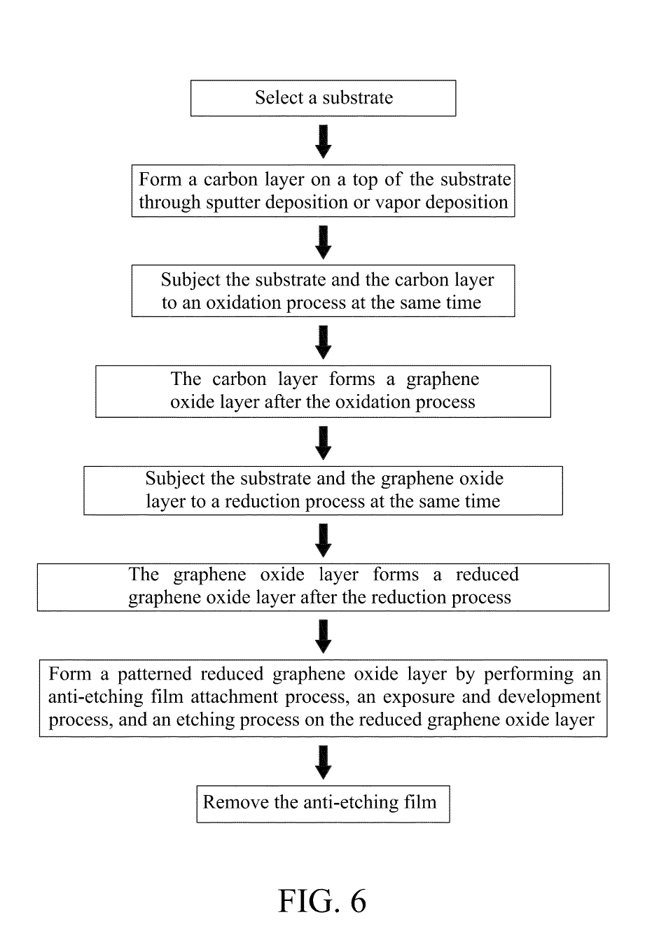

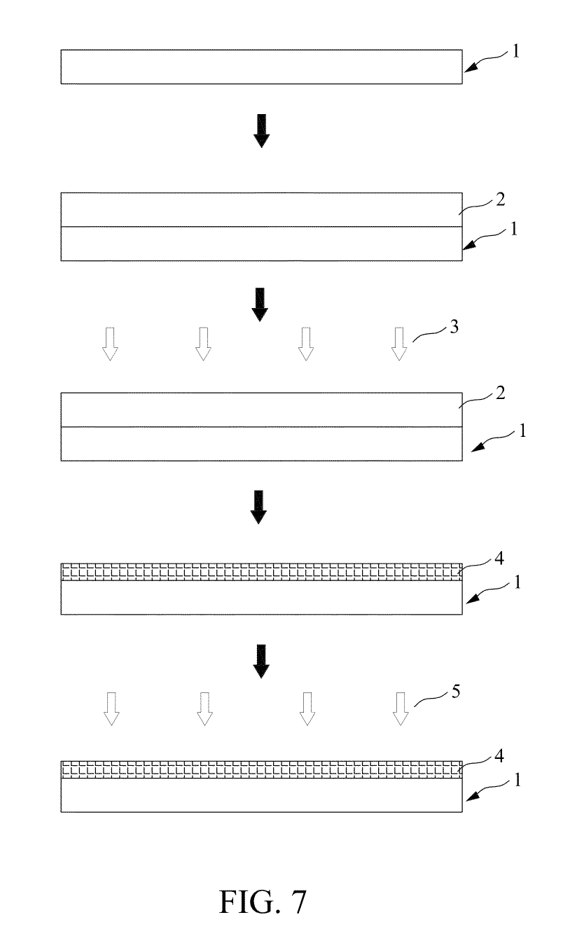

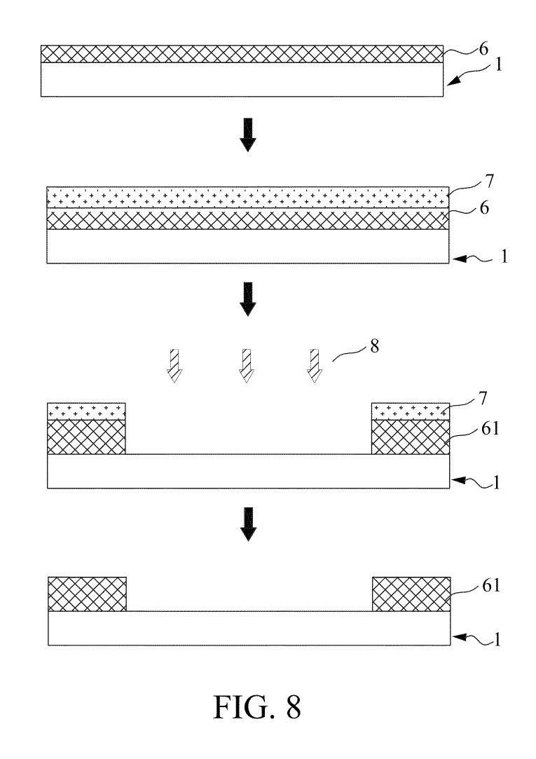

FIG. 6 is a flowchart showing the steps included in a third embodiment of the method according to the present invention, and FIGS. 7 and 8 are a pictorial description of the steps in FIG. 6. As shown, the third embodiment of the method according to the present invention includes the following steps:
(A) selecting a substrate 1;
(B) forming a carbon layer 2 on a top of the substrate 1 through sputter deposition or vapor deposition;
(C) subjecting the substrate 1 and the carbon layer 2 to an oxidation process 3 at the same time;
(D) the carbon layer 2 forming a graphene oxide layer 4 after the oxidation process 3;
(E) subjecting the substrate 1 and the graphene oxide layer 4 to a reduction process 5 at the same time;
(F) the graphene oxide layer 4 forming a reduced graphene oxide layer 6 after the reduction process 5;
(G) forming a patterned reduced graphene oxide layer 61 by performing an anti-etching film 7 attachment process, an exposure and development process 8, and an etching process on the reduced graphene oxide layer 6; and
(H) removing the anti-etching film 7.

The substrate 1 selected in the step (A) can have a structure illustrated in any one of FIGS. 3A and 3B.

In the step (B), at least one carbon layer 2 is formed on the surface of the substrate 1 by sputter depositing or vapor depositing a carbon material onto the substrate 1.

After the carbon layer 2 is formed through sputter deposition or vapor deposition in the step (B), the substrate 1 and the carbon layer 2 formed thereon are together subjected to an oxidation process 3 in the step (C).

In the step (D), after the oxidation process 3, the carbon layer 2 forms a graphene oxide layer 4.

In the step (E), the substrate 1 and the graphene oxide layer 4 formed thereon are together subjected to a reduction process 5.

In the step (F), after the reduction process 5, the graphene oxide layer 4 is reduced to form a reduced graphene oxide layer 6.

Then, in the step (G), an anti-etching film 7 attachment process, an exposure and development process 8 as well as an etching process are performed on the reduced graphene oxide layer 6 to obtain a patterned reduced graphene oxide layer 61 before the anti-etching film 7 is removed from the top of the patterned reduced graphene oxide layer 61 in the step (H).

Wherein, in the anti-etching film 7 attachment process, a dry film 7 or a wet film 7 formed of an ultraviolet-reactive polymeric resin is attached to a top of the substrate 1 within an area, on which the patterned reduced graphene oxide layer 61 is to be formed. The anti-etching film 7, after polymerization, is mainly used to protect the desired pattern from being etched away in the subsequent etching process.

In the exposure session of the exposure and development process 8, a positive mask made according to a predetermined circuit pattern is first aligned with and flatly spread on the area already having the anti-etching film 7 attached thereto. Then, use an exposure machine to complete the processes of vacuuming, lamination and ultraviolet irradiation on the anti-etching film 7. The anti-etching film 7 being irradiated by ultraviolet rays will be polymerized. However, area of the anti-etching film 7 that is shielded by the mask and forms the circuit pattern is protected from irradiation by the violet rays and is therefore not polymerized.

In the development session of the exposure and development process 8, use an developer to mechanically or chemically strip off the portion of the anti-etching film 7 that is not polymerized, so that the circuit pattern that is to be reserved is shown. The pattern formed through the exposure and development process shows fine, straight and smooth lines.

The etching process can be divided into two types, namely, wet etching and dry etching. The wet etching is also known by chemical etching, in which a chemical solution is used to produce a chemical reaction and achieve an etching effect. In the dry etching, an inert gas or a reactive gas is used, so that the material to be removed is exposed to a bombardment of ions. In other words, the portion that is not shielded by the anti-etching film 7 is physically etched and removed. By using the above two types of etching process, the surface area of the patterned reduced graphene oxide layer 61 that is not shielded by the anti-etching film 7 is etched off. Then, the remained anti-etching film 7 is stripped off.

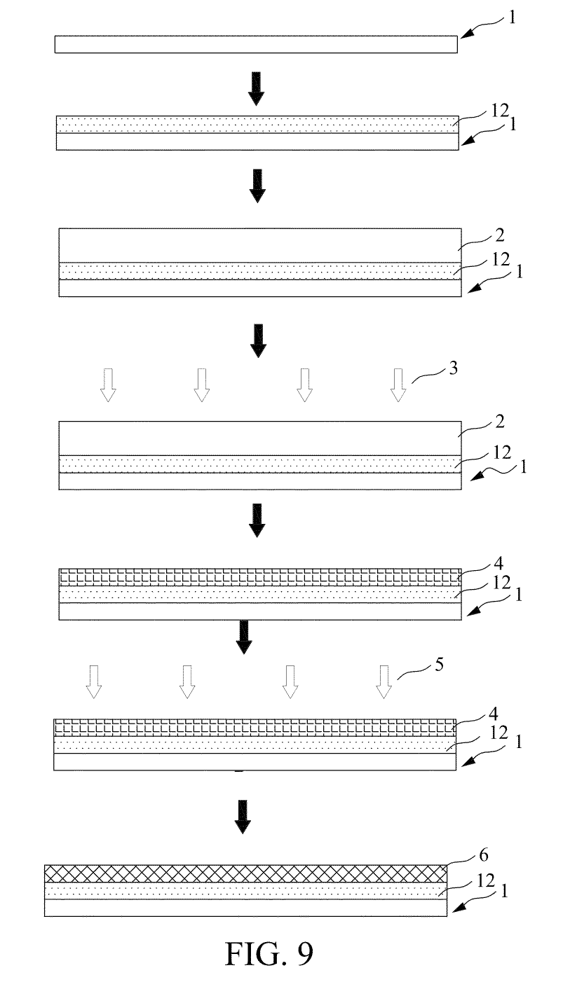

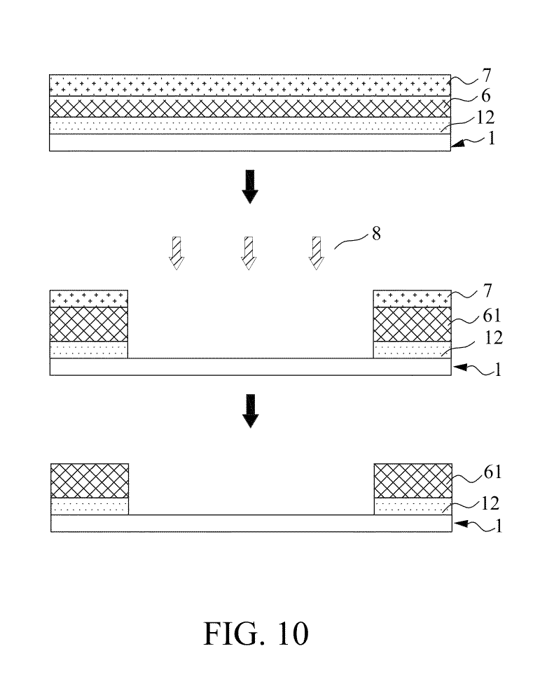

Please refer to FIG. 6 along with FIGS. 9 and 10. In a fourth embodiment of the method according to the present invention, the substrate 1 selected in the step (A) can be formed of a metal material 10a having another metal material 12, such as metal nickel or a nickel alloy, sputter deposited or vapor deposited onto a top thereof, and is therefore a dual-layer structured substrate 1, as shown in FIG. 5A.

Alternatively, according to another operable form of the fourth embodiment, the substrate 1 selected in the step (A) can be formed of a non-metal material 11 a having a metal material 12, such as metal nickel, a nickel alloy, chrome, a chrome alloy, titanium or a titanium alloy, sputter deposited or vapor deposited onto a top thereof, and is therefore a dual-layer structured substrate 1, as shown in FIG. 5B.

The fourth embodiment is different from the third embodiment only in that, in the step (A), the metal material 10a or the non-metal material 11 a further has a metal material 12 sputter deposited or vapor deposited thereon. Since all other steps from (B) to (H) are the same as those in the third embodiment, they are not repeatedly described herein.

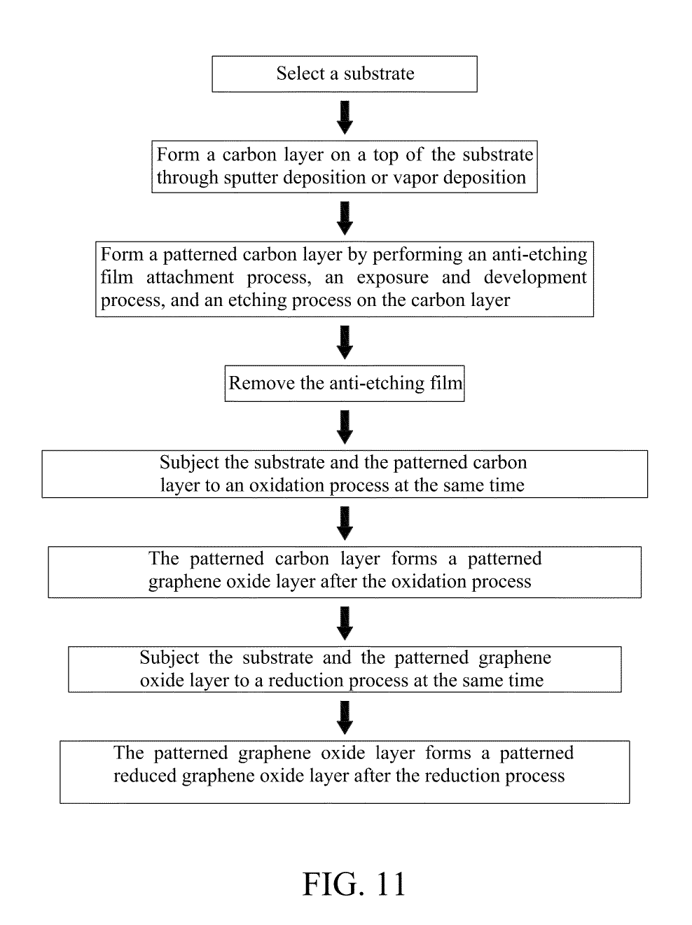

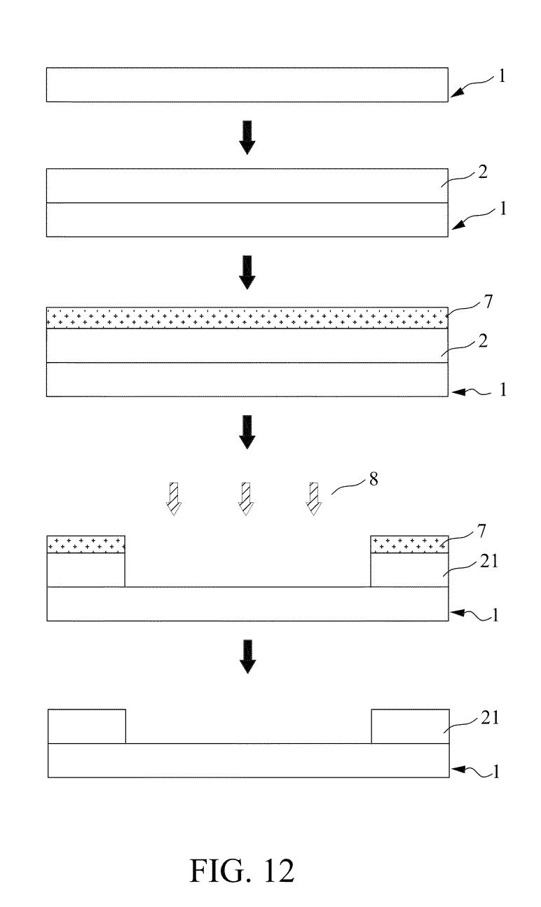

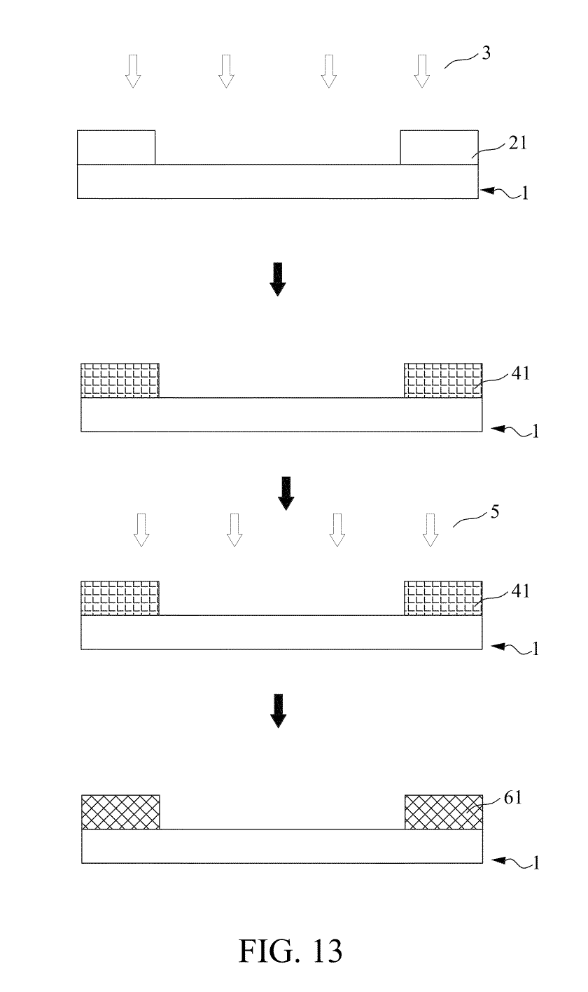

FIG. 11 is a flowchart showing the steps included in a fifth embodiment of the method according to the present invention, and FIGS. 12 and 13 are a pictorial description of the steps shown in FIG. 11. As shown, the fifth embodiment of the method according to the present invention includes the following steps:
(A) selecting a substrate 1;
(B) forming a carbon layer 2 on a top of the substrate 1 through sputter deposition or vapor deposition;
(C) forming a patterned carbon layer 21 by performing an anti-etching film 7 attachment process, an exposure and development process 8, and an etching process on the carbon layer 2;
(D) removing the anti-etching film 7;
(E) subjecting the substrate 1 and the patterned carbon layer 21 to an oxidation process 3 at the same time;
(F) the patterned carbon layer 21 forming a patterned graphene oxide layer 41 after the oxidation process 3;
(G) subjecting the substrate 1 and the patterned graphene oxide layer 41 to a reduction process 5 at the same time; and
(H) the patterned graphene oxide layer 41 forming a patterned reduced graphene oxide layer 61 after the reduction process 5.

The substrate 1 selected in the step (A) can have a structure illustrated in any one of FIGS. 3A and 3B.

In the step (B), at least one carbon layer 2 is formed on the top of the substrate 1 by sputter depositing or vapor depositing a carbon material onto the substrate 1.

After the carbon layer 2 is formed through sputter deposition or vapor deposition in the step (B), an anti-etching film 7 attachment process, an exposure and development process 8 as well as an etching process are performed on the carbon layer 2 to obtain a patterned carbon layer 21 in the step (C).

After the anti-etching film 7 is stripped off in the step (D), the substrate 1 and the patterned carbon layer 21 are subjected to an oxidation process 3 at the same time in the step (E).

In the step (F), the patterned carbon layer 21 after the oxidation process 3 forms a patterned graphene oxide layer 41.

In the step (G), the substrate 1 and the patterned graphene oxide layer 41 are subjected to a reduction process 5 at the same time.

Finally, in the step (H), after the reduction process 5, the patterned graphene oxide layer 41 forms a patterned reduced graphene oxide layer 61.

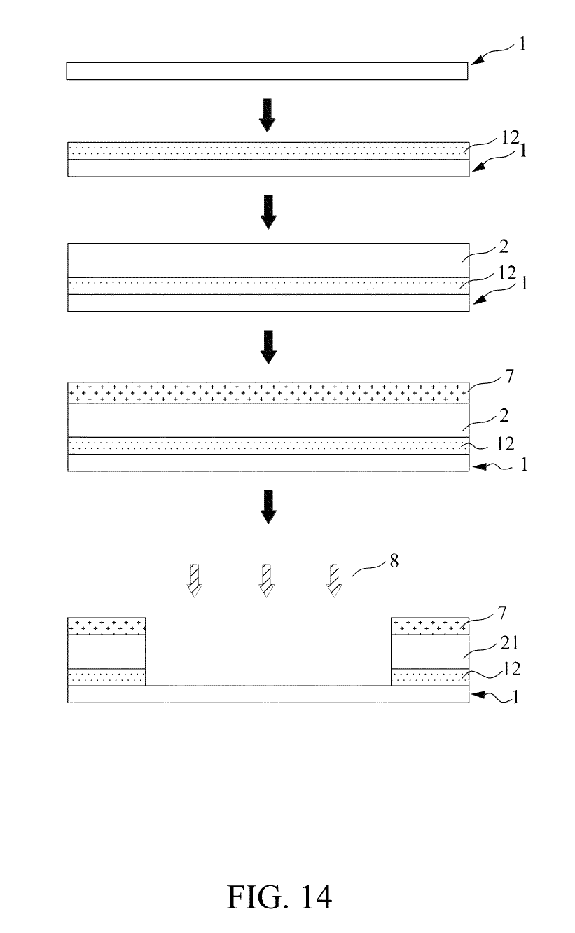

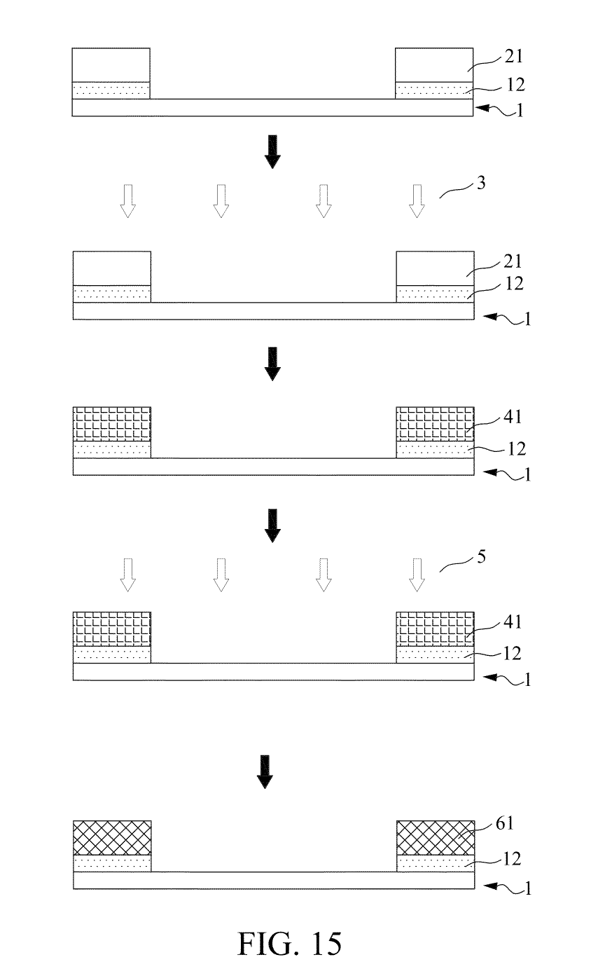

Please refer to FIG. 11 along with FIGS. 14 and 15. In a sixth embodiment of the method according to the present invention, the substrate 1 selected in the step (A) can be formed of a metal material 10a having another metal material 12, such as metal nickel or a nickel alloy, sputter deposited or vapor deposited onto a top thereof, and is therefore a dual-layer structured substrate 1, as shown in FIG. 5A.

Alternatively, according to another operable form of the sixth embodiment, the substrate 1 selected in the step (A) can be formed of a non-metal material 11 a having a metal material 12, such as metal nickel, a nickel alloy, chrome, a chrome alloy, titanium or a titanium alloy, sputter deposited or vapor deposited onto a top thereof, and is therefore a dual-layer structured substrate 1, as shown in FIG. 5B.

As can be seen from FIGS. 14 and 15, the sixth embodiment of the method according to the present invention is different from the fifth embodiment only in the step (A). Since all other steps from (B) to (H) are the same as those in the fifth embodiment, they are not repeatedly described herein.

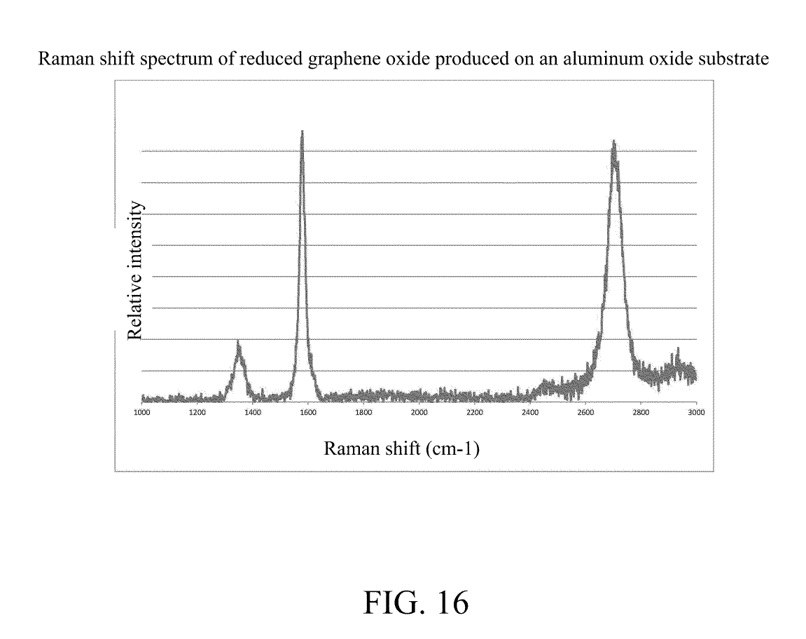

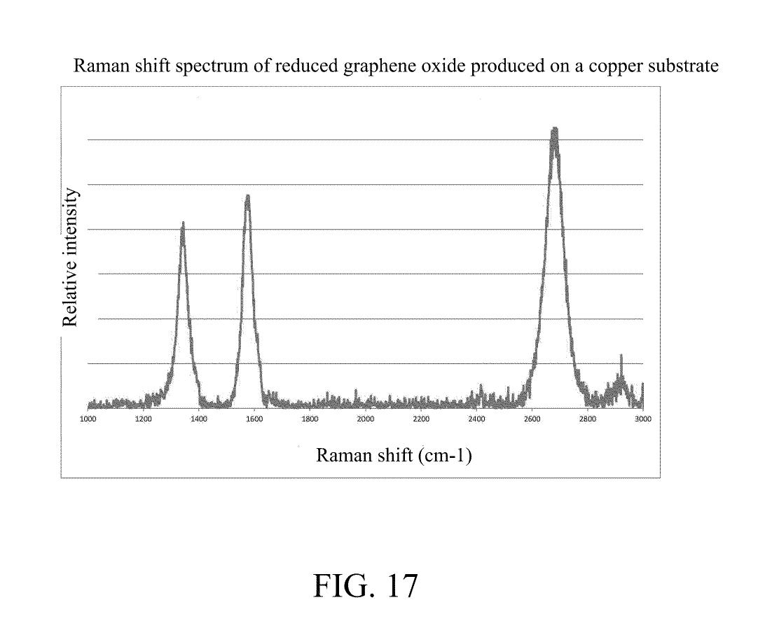

Please refer to FIGS. 16 and 17, wherein FIG. 16 is a Raman shift spectrum of the reduced graphene oxide produced on an aluminum oxide substrate according to the method of the present invention, and FIG. 17 is a Raman shift spectrum of the reduced graphene oxide produced on a copper substrate according to the method of the present invention. The Raman spectrum of graphene shows three characteristic peaks, namely, a D band peak that indicates the structure of carbon sp³ bonds in the graphene, a G band peak that indicates the carbon sp² bonds in the graphene, and a 2D band peak that would slightly shift and change with the number of layers of the graphene. Therefore, the two-dimensional distribution of the G-peak value shown in the Raman shift spectrum reflects the coverage uniformity and the quality level of the graphene crystals. Further, the 2D band peak with smaller full width at half maximum and larger 2D-peak value indicates the graphene has fewer layers and better crystallinity. Thus, it can be seen from the two Raman shift spectra shown in FIGS. 16 and 17 that the reduced graphene oxide produced according to the method of the present invention is good in quality.

The present invention is characterized in growing the reduced graphene oxide directly on a metal or a non-metal substrate without the need of any additional transfer process, which advantageously prevents the produced graphene oxide from any stress-induced damage. Further, while the conventional manufacturing process produces reduced graphene oxide powder, the method of the present invention enables the production of reduced graphene oxide layers having a highly dense and firm structure. The method of the present invention provides a simple and economical manufacturing process for quickly producing high-quality reduced graphene oxide sheet at largely reduced cost to satisfy the market demand for wider application of graphene in commercial and industrial fields.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A method of producing reduced graphene oxide, comprising the following steps:
(A) selecting a substrate;
(B) forming a carbon layer on a top of the substrate through sputter deposition or vapor deposition;
(C) subjecting the substrate and the carbon layer to an oxidation process at the same time;
(D) the carbon layer forming a graphene oxide layer on the surface of the substrate after the oxidation process;
(E) subjecting the substrate and the graphene oxide layer to a reduction process at the same time; and
(F) the graphene oxide layer forming a reduced graphene oxide layer after the reduction process.

2. The method as claimed in claim 1, wherein the substrate is selected from the group consisting of a metal substrate and a non-metal substrate.

3. The method as claimed in claim 2, wherein the metal substrate is selected from the group consisting of a single metal material and a single alloy material.

4. The method as claimed in claim 2, wherein the metal substrate is formed of a metal material having another metal material sputter deposited or vapor deposited onto a top thereof, and the other metal material being selected from the group consisting of metal nickel and a nickel alloy.

5. The method as claimed in claim 2, wherein the non-metal substrate is selected from the group consisting of a ceramic substrate, a glass substrate, a semiconductor substrate, an engineering plastic substrate, a quartz substrate and a sapphire substrate, which all are formed of a non-metal material.

6. The method as claimed in claim 2, wherein the non-metal substrate is formed of a non-metal material having a metal material sputter deposited or vapor deposited onto a top thereof, and the metal material being selected from the group consisting of metal nickel, a nickel alloy, chrome, a chrome alloy, titanium and a titanium alloy.

7. The method as claimed in claim 1, wherein a temperature for the oxidation process is set to range between 200 and 1500° C.

8. The method as claimed in claim 1, wherein the oxidation process is selected from the group consisting of an atmosphere heat treatment, an atmosphere-oxygen reaction type heat treatment and a vacuum-oxygen reaction type heat treatment.

9. The method as claimed in claim 8, wherein, in the atmosphere-oxygen reaction type heat treatment, an amount of oxygen is supplied into an inert gas.

10. The method as claimed in claim 8, wherein, in the vacuum-oxygen reaction type heat treatment, an amount of oxygen is supplied into a vacuum space.

11. The method as claimed in claim 1, further comprising a step (G) after the step (F) to form a patterned reduced graphene oxide layer by performing an anti-etching film attachment process, an exposure and development process, and an etching process on the reduced graphene oxide layer.

12. A method of producing reduced graphene oxide, comprising the following steps:
(A) selecting a substrate;
(B) forming a carbon layer on a top of the substrate through sputter deposition or vapor deposition;
(C) forming a patterned carbon layer by performing an anti-etching film attachment process, an exposure and development process, and an etching process on the carbon layer;
(D) removing the anti-etching film;
(E) subjecting the substrate and the patterned carbon layer to an oxidation process at the same time;
(F) the patterned carbon layer forming a patterned graphene oxide layer after the oxidation process;
(G) subjecting the substrate and the patterned graphene oxide layer to a reduction process at the same time; and
(H) the patterned graphene oxide layer forming a patterned reduced graphene oxide layer after the reduction process.

13. The method as claimed in claim 12, wherein the substrate is selected from the group consisting of a metal substrate and a non-metal substrate.

14. The method as claimed in claim 13, wherein the metal substrate is selected from the group consisting of a single metal material and a single alloy material.

15. The method as claimed in claim 13, wherein the metal substrate is formed of a metal material having another metal material sputter deposited or vapor deposited onto a top thereof, and the other metal material being selected from the group consisting of metal nickel and a nickel alloy.

16. The method as claimed in claim 13, wherein the non-metal substrate is selected from the group consisting of a ceramic substrate, a glass substrate, a semiconductor substrate, an engineering plastic substrate, a quartz substrate and a sapphire substrate, which all are formed of a non-metal material.

17. The method as claimed in claim 13, wherein the non-metal substrate is formed of a non-metal material having a metal material sputter deposited or vapor deposited onto a top thereof, and the metal material being selected from the group consisting of metal nickel, a nickel alloy, chrome, a chrome alloy, titanium and a titanium alloy.

18. The method as claimed in claim 12, wherein a temperature for the oxidation process is set to range between 200 and 1500° C.

19. The method as claimed in claim 12, wherein the oxidation process is selected from the group consisting of an atmosphere heat treatment, an atmosphere-oxygen reaction type heat treatment, and a vacuum-oxygen reaction type heat treatment.

20. The method as claimed in claim 19, wherein, in the atmosphere-oxygen reaction type heat treatment, an amount of oxygen is supplied into an inert gas.

21. The method as claimed in claim 19, wherein, in the vacuum-oxygen reaction type heat treatment, an amount of oxygen is supplied into a vacuum space.
